(19) United States
(12) Patent Application Publication
(10) Pub. No.: US 2026/0362649 A1
(43) Pub. Date: Nov. 12, 2026

(54) SERVER AND CABINET

(71) Applicants: SQ TECHNOLOGY (SHANGHAI) CORPORATION, Shanghai (CN); INVENTEC CORPORATION, Taipei (TW)

(72) Inventors: Zhao Geng, Shanghai (CN); Guangzhao Tian, Shanghai (CN); Hong-Chou Lin, Taipei (TW); Yu-Fan Chen, Taipei (TW)

(21) Appl. No.: 19/263,455

(22) Filed: Jul. 8, 2025

(30) Foreign Application Priority Data
May 9, 2025 (CN) 202510599971.0

(51) Int. Cl. H05K 7/20

(52) U.S. Cl. CPC H05K 7/20772; H05K 7/20172; H05K 7/20272; H05K 7/20727

(57) ABSTRACT

A server includes a bottom frame including a first mounting area and a second mounting area, the bottom frame being provided with a liquid outlet in communication with the first mounting area; a first function assembly provided in the first mounting area; a second function assembly provided in the second mounting area; a liquid cooling assembly cooperating with the first function assembly and configured to dissipate heat for the first function assembly; a first barrier structure provided on the bottom frame and configured to separate the first mounting area from the second mounting area; and a liquid guiding structure provided on the bottom frame and configured to guide a leaked liquid from the liquid cooling assembly to flow toward the liquid outlet.

### CROSS-REFERENCE TO RELATED APPLICATIONS

This application claims priority to Chinese Patent Application No. 2025105999710, filed on May 9, 2025, the content of which is hereby incorporated by reference in its entirety.

### TECHNICAL FIELD

The present disclosure relates to the technical field of computing devices, and in particular to a server and a cabinet.

### BACKGROUND

Server is a specific IT (information technology) device that provides computing power and runs software applications in a network environment and is configured to provide computing or application services to other clients, such as personal computers, smart phones, ATMs, etc., in the network. The server generates a lot of heat during operation, causing its temperature to continuously rise. If the server is not cooled in time, the operating performance and stability of the server will be adversely affected.

Currently, the main cooling methods for the server are air convection cooling or fan cooling. However, in the server with high integration and high power density, the air convection cooling or fan cooling can no longer meet the cooling requirements and causes problems such as high noise and low energy efficiency. In view of this, liquid cooling technology has gradually become a more effective cooling method for cooling the server. The liquid cooling technology takes away the heat generated inside the server through liquid circulation, which has the advantages of high heat dissipation efficiency, low noise and high energy efficiency. However, in actual application, a server liquid cooling casing has some problems, the most serious of which is liquid leakage. Once liquid leakage occurs, it will not only damage the hardware inside the server, but also cause safety hazards in the data center, and may even lead to the paralysis of the entire data center.

### SUMMARY

Accordingly, it is necessary to provide a server and a cabinet to address the problem of potential safety hazards caused by liquid leakage.

A server includes a bottom frame including a first mounting area and a second mounting area, the bottom frame being provided with a liquid outlet in communication with the first mounting area; a first function assembly provided in the first mounting area; a second function assembly provided in the second mounting area; a liquid cooling assembly cooperating with the first function assembly and configured to dissipate heat for the first function assembly; a first barrier structure provided on the bottom frame and configured to separate the first mounting area from the second mounting area; and a liquid guiding structure provided on the bottom frame and configured to guide a leaked liquid from the liquid cooling assembly to flow toward the liquid outlet.

In the server, the first function assembly and the second function assembly are mounted in the first mounting area and the second mounting area of the bottom frame respectively, and the liquid cooling assembly cooperates with the first function assembly, when the first function assembly generates heat during operation, the liquid cooling assembly can timely and effectively perform liquid cooling on the first function assembly, thereby preventing the first function assembly and the server from being overheated and affecting the working efficiency and reliability. Further, the first barrier structure is provided between the first mounting area and the second mounting area, that is, the first function assembly and the liquid cooling assembly are separated from the second function assembly by the first barrier structure. In this way, even if the liquid cooling assembly leaks, the leaked liquid is blocked by the first barrier structure and cannot flow into the second mounting area, and then cannot be in contact with the second function assembly. At this time, the leaked liquid is guided by the liquid guiding structure to flow toward the liquid outlet and is finally discharged from the liquid outlet, thereby preventing the leaked liquid from damaging the second function assembly, eliminating potential safety hazards, and protecting the safety of the server.

In one embodiment, the liquid guiding structure includes a protrusion structure arranged in the first mounting area.

In one embodiment, the liquid guiding structure includes a protrusion structure and a sloping surface that are arranged in the first mounting area, the sloping surface has a first side and a second side that are opposite to each other, a height of the first side is greater than a height of the second side, the first side is connected to the protrusion structure, and the second side is connected to the liquid outlet.

In one embodiment, the first barrier structure includes a barrier wall and a first adhesive member, the barrier wall is provided on the bottom frame, the first adhesive member bonds and seals the barrier wall to the bottom frame, and the first adhesive member is arranged in the first mounting area or the second mounting area.

In one embodiment, the first barrier structure includes a barrier wall, a first adhesive member, and a second adhesive member; the barrier wall is provided on the bottom frame, the first adhesive member bonds and seals the barrier wall to the bottom frame and is arranged in the first mounting area, and the second adhesive member bonds and seals the barrier wall to the bottom frame and is arranged in the second mounting area.

In one embodiment, the first function assembly includes at least one mainboard, the liquid cooling assembly includes at least one liquid cooling component, a liquid inlet pipe, and a liquid outlet pipe; the liquid cooling assembly is mounted on the mainboard to dissipate heat for the mainboard, the liquid inlet pipe is in communication with a liquid inlet of the liquid cooling component, and the liquid outlet pipe is in communication with a liquid outlet of the liquid cooling component.

In one embodiment, the at least one mainboard include a first mainboard and a second mainboard that are arranged side by side, the at least one liquid cooling component includes a first liquid cooling component and a second liquid cooling component, the first liquid cooling component is mounted on the first mainboard, the second liquid cooling component is mounted on the second mainboard.

In one embodiment, the liquid cooling assembly further includes a first liquid conveying pipe, a second liquid conveying pipe, a first liquid return pipe, a second liquid return pipe, a first liquid distributor, and a second liquid distributor; the first liquid distributor is connected to the liquid inlet pipe, one end of the first liquid conveying pipe and one end of the second liquid conveying pipe are both connected to the first liquid distributor, another end of the first liquid conveying pipe is connected to the first liquid cooling component, another end of the second liquid conveying pipe is connected to the second liquid cooling component, one end of the first liquid return pipe is connected to the first liquid cooling component, one end of the second liquid return pipe is connected to the second liquid cooling component, another end of the first liquid return pipe and another end of the second liquid return pipe are both connected to the second liquid distributor, and the second liquid distributor is connected to the liquid outlet pipe.

In one embodiment, the liquid inlet pipe and the liquid outlet pipe are both designed with a quick-disassembly structure.

In one embodiment, the second function assembly includes a power supply and a fan assembly, and the power supply is located closer to the first function assembly than the fan assembly, and the fan assembly is arranged at an edge of the bottom frame.

In one embodiment, the fan assembly includes a mounting box and a plurality of fans, the mounting box includes a plurality of mounting chambers arranged side by side on a side thereof away from the power supply, the plurality of fans are mounted in the plurality of mounting chambers in a one-to-one correspondence, and the mounting box or the bottom frame is provided with a positioning member configured to be engaged with a positioning hole of a cabinet body.

In one embodiment, each fan is provided with a handle, the liquid inlet pipe and the liquid outlet pipe are both provided with a buckle, and the buckle is engaged with the handle.

In one embodiment, the bottom frame includes a third mounting area located on a side of the first mounting area away from the second mounting area, and the server further includes a third function assembly provided in the third mounting area.

In one embodiment, the server further includes a second barrier structure provided on the bottom frame, and the second barrier structure is arranged between the third mounting area and the first mounting area.

A cabinet is further provided, including a cabinet body and a plurality of servers as described above. The cabinet body is provided with a mounting cavity therein, and the plurality of servers are stacked in the mounting cavity along a height direction of the cabinet body.

The details of one or more embodiments of the application are set forth in the accompanying drawings and the description below. Other features, objects, and advantages of the application will be apparent from the description and drawings, and from the claims.

### BRIEF DESCRIPTION OF THE DRAWINGS

The drawings constitute a part of the present disclosure and are used to provide a further understanding of the present disclosure. The exemplary embodiments of the present disclosure and their descriptions are used to explain the present disclosure and do not constitute an improper limitation of the present disclosure.

In order to illustrate the embodiments of the present disclosure more clearly, the drawings used in the embodiments will be described briefly. Apparently, the following described drawings are merely for the embodiments of the present disclosure, and other drawings can be derived by those of ordinary skill in the art without any creative effort.

FIG. 1 is a partial exploded view of a server according to an embodiment.

FIG. 2 is a top view of the server without a top cover.

FIG. 3 is a schematic view illustrating a distribution of a first mounting area, a second mounting area, a third mounting area, a first barrier structure and a second barrier structure on a bottom frame of the server.

FIG. 4 is a perspective view of the server without the top cover.

FIG. 5 is an enlarged view of a portion A in FIG. 4.

FIG. 6 is a schematic view of the first barrier structure according to an embodiment.

### DESCRIPTION OF REFERENCE NUMERALS

100, server; 10, bottom frame; 11, first mounting area; 12, second mounting area; 13, liquid outlet; 14, third mounting area; 20, top cover; 30, first function assembly; 31, first mainboard; 32, second mainboard; 40, second function assembly; 41, power supply; 42, fan assembly; 421, mounting box; 422. fan; 422. handle; 50. liquid cooling assembly; 51. liquid inlet pipe; 52. liquid outlet pipe; 53. first liquid cooling component; 54. second liquid cooling component; 55. first liquid distributor; 56. second liquid distributor; 57. first liquid conveying pipe; 57a. second liquid conveying pipe; 58. first liquid return pipe; 58a, second liquid return pipe; 60, first barrier structure; 61, barrier wall; 62, first adhesive member; 63, second adhesive member; 70, liquid guiding structure; 80, positioning member; 90, buckle; 90a, third function assembly; 90b, second barrier structure.

### DETAILED DESCRIPTION OF THE EMBODIMENTS

In order to make the above objectives, features and advantages of the present disclosure clear and easier to understand, the specific embodiments of the present disclosure are described in detail below in combination with the accompanying drawings. Many specific details are set forth in the following description to facilitate a full understanding of the present disclosure. However, the present disclosure can be implemented in many ways different from those described herein, and those skilled in the art can make similar improvements without departing from the connotation of the present disclosure. Therefore, the present disclosure is not limited by the specific embodiments disclosed below.

In the description of the present disclosure, it should be understood that the terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential direction” are based on the azimuths or position relationships shown in the attached drawings. These terms are only for the convenience of describing the present disclosure and simplifying the description, rather than indicating or implying that the indicated devices or elements must have the specific azimuths, or be constructed or operated in the specific azimuths, and therefore such terms cannot be understood as limitations of the present disclosure.

In addition, the terms “first” and “second” are only used for descriptive purposes and cannot be understood as indicating or implying relative importance or implicitly indicating the number of indicated technical features. Thus, the features defined with “first” and “second” may explicitly or implicitly include at least one of the features. In the description of the present disclosure, “a plurality of” means at least two, such as two, three, etc., unless otherwise expressly and specifically defined.

In the present disclosure, unless otherwise expressly specified and limited, the terms “mount”, “connect”, “couple”, “fix” and the like should be interpreted broadly. For example, the terms can mean fixed connection, detachable connection, or being integrated. The terms can mean mechanical connection or electrical connection. The terms can mean directly connection or indirectly connection through an intermediate medium. The terms can mean connection within two elements or interaction relationship between two elements, unless otherwise expressly limited. For those skilled in the art, the specific meaning of the above terms in the present disclosure should be understood according to the specific situation.

In the present disclosure, unless otherwise expressly specified and limited, a first feature “above” or “below” a second feature may be in direct contact with the second feature, or the first and second features may be in indirect contact through an intermediate medium. Moreover, the first feature “above” the second feature may be right above or obliquely above the second feature, or the first feature may be merely located at a height higher than the second feature. The first feature “below” the second feature may be right below or obliquely below the second feature, or the first feature may be merely located at a height lower than that of the second feature.

It should be noted that when an element is called “fixed to” or “provided on” another element, it can be directly on another element or there can be an intermediate element. When an element is considered to be “connected” to another element, it can be directly connected to another element or there can be an intermediate element. The terms “vertical”, “horizontal”, “up”, “down”, “left”, “right” and similar expressions used herein are for the purpose of illustration only and do not represent the only ways for implementation.

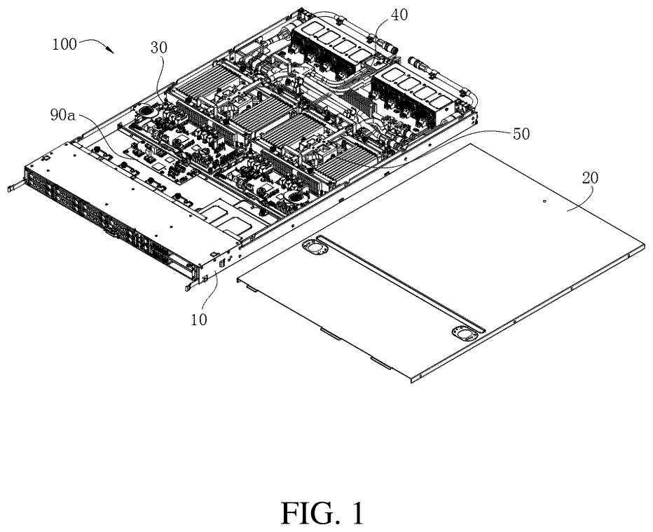

Referring to FIG. 1, a server 100 is provided according to an embodiment of the present disclosure. For example, the server 100 may be, but is not limited to, a 1U server. In a network environment, the server 100 is a specific IT device that can provide computing power and run software applications and is configured to provide computing or application services to other clients, such as personal computers, smart phones, ATMs, etc., in the network.

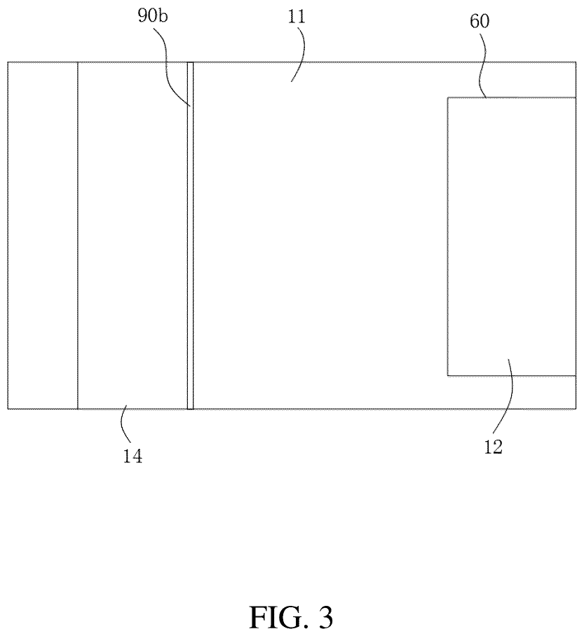

Referring to FIGS. 1 to 3, in an embodiment, the server 100 includes a top cover 20, a bottom frame 10, a liquid cooling assembly 50, a first barrier structure 60, and a liquid guiding structure 70.

The top cover 20 is assembled with the bottom frame 10 to form a housing of the server 100. The top cover 20 and the bottom frame 10 enclose an accommodating cavity, which serves as a space for mounting various function assemblies. In addition, the housing is also used to enclose and protect the function assemblies mounted therein.

Further, since the function assemblies continuously generate a large amount of heat during operation, in order to effectively dissipate the heat to the external environment in time, the top cover 20 and/or the bottom frame 10 are provided with heat dissipation holes.

In an embodiment, the heat dissipation holes are provided at positions of the top cover 20 and the bottom frame 10 that are opposite to each other. The heat dissipation holes on both sides are configured to form air convection, so that heat can be taken away from the server 100 through air.

In another embodiment, other heat dissipation technologies can also be applied to the server 100, which can be flexibly selected according to actual needs, and will not be described herein.

The bottom frame 10 includes a first mounting area 11 and a second mounting area 12. The function assemblies includes a first function assembly 30 provided in the first mounting area 11, and a second function assembly 40 provided in the second mounting area 12. The bottom frame 10 is provided with a liquid outlet 13 in communication with the first mounting area 11.

The liquid cooling assembly 50 cooperates with the first function assembly 30 and is configured to dissipate heat for the first function assembly 30. The first barrier structure 60 is provided on the bottom frame 10 and is configured to separate the first mounting area 11 from the second mounting area 12.

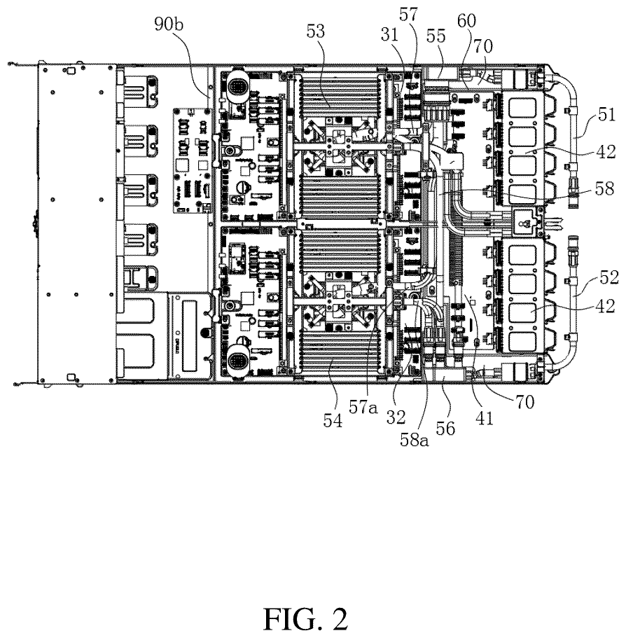

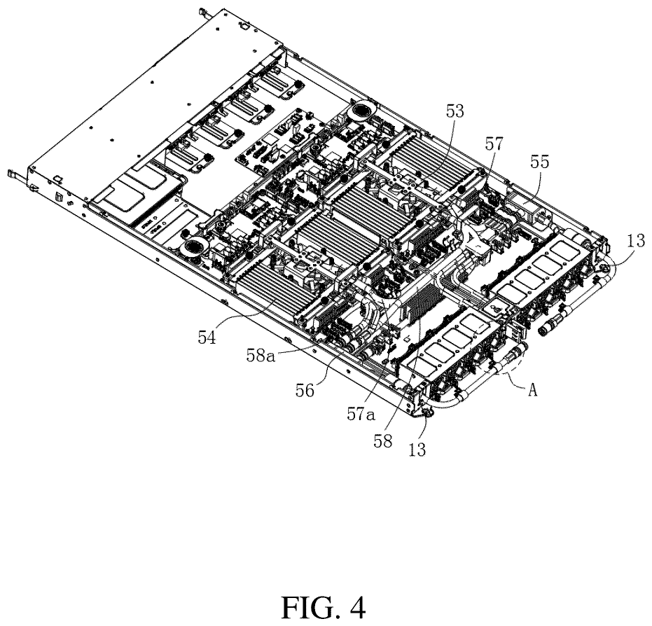

Referring to FIG. 2 and FIG. 4, the liquid guiding structure 70 is provided on the bottom frame 10 and is configured to guide the leaked liquid from the liquid cooling assembly 50 to flow toward the liquid outlet 13.

It should be understood that the first function assembly 30 includes a device that can be in contact with the leaked liquid without affecting normal operation thereof, and the second function assembly 40 includes a device that cannot be in contact with the leaked liquid, so as to avoid damage problems such as short circuit and corrosion.

In summary, according to the server 100, the first function assembly 30 and the second function assembly 40 are mounted in the first mounting area 11 and the second mounting area 12 that are predetermined on the bottom frame 10, respectively. The liquid cooling assembly 50 cooperates with the first function assembly 30, when the first function assembly 30 generates heat during operation, the liquid cooling assembly 50 can timely and effectively perform liquid cooling on the first function assembly 30, thereby preventing the first function assembly 30 from being overheated and affecting the working efficiency and reliability of the server 100. Further, the first barrier structure 60 is provided between the first mounting area 11 and the second mounting area 12, that is, the first function assembly 30 and the liquid cooling assembly 50 are separated from the second function assembly 40 by the first barrier structure 60. In this way, even if the liquid cooling assembly 50 leaks, the leaked liquid is blocked by the first barrier structure 60 and cannot flow into the second mounting area 12, thus the leaked liquid cannot be in contact with the second function assembly 40. At this time, the leaked liquid is guided by the liquid guiding structure 70 to flow toward the liquid outlet 13 and is finally discharged from the liquid outlet 13, thereby preventing the leaked liquid from damaging the second function assembly 40, eliminating potential safety hazards, and protecting the safety of the server 100.

In order to enable the liquid guiding structure 70 to guide the leaked liquid to flow toward the liquid outlet 13 to avoid the accumulation of the leaked liquid in the bottom frame 10 and causing the safety hazard, in an optional embodiment, the liquid guiding structure 70 includes a protrusion structure arranged in the first mounting area 11.

Specifically, a side surface of the bottom frame 10 configured to mount the first function assembly 30 and the second function assembly 40 is defined as a mounting surface. The protrusion structure protrudes towards the mounting surface by a certain height. It should be noted that the height of the protrusion structure should not affect the mounting of the function assemblies, the top cover 20, etc. The shape, size, number, etc. of the protrusion structure can be flexibly designed according to actual needs, and are not specifically limited herein.

In actual processing, the protrusion structure can be formed by stamping, extrusion and other processing methods.

Due to the relative mounting positions and size relationships of the function assemblies and other components, there is a long distance between the protrusion structure and the liquid outlet 13, and the protrusion structure may not be able to guide the leaked liquid to flow continuously and reach the liquid outlet 13 quickly and effectively. In view of this, in another optional embodiment, the liquid guiding structure 70 includes the protrusion structure and a sloping surface, both of which are arranged in the first mounting area 11. The sloping surface has a first side and a second side that are opposite to each other, a height of the first side is greater than a height of the second side, the first side is connected to the protrusion structure, and the second side is connected to the liquid outlet 13.

When liquid leakage occurs, the protrusion structure first provides initial kinetic energy for the leaked liquid to flow toward the liquid outlet 13. In this way, the leaked liquid continues to flow toward the liquid outlet 13 along the sloping surface, and the gravitational potential energy of the leaked liquid is increased by the sloping surface with a slope, so that the leaked liquid can continuously obtain the kinetic energy for flow, thereby being able to accelerate to reach the liquid outlet 13, so that the leaked liquid can be discharged timely and effectively.

In an optional embodiment, the first barrier structure 60 includes a barrier wall 61 and a first adhesive member 62. The barrier wall 61 is provided on the bottom frame 10. The first adhesive member 62 bonds and seals the barrier wall 61 to the bottom frame 10, and the first adhesive member 62 is arranged in the first mounting area 11 or the second mounting area 12.

Referring to FIG. 6, as an alternative to the above embodiment, the first barrier structure 60 may include a barrier wall 61, a first adhesive member 62, and a second adhesive member 63. The barrier wall 61 is provided on the bottom frame 10. The first adhesive member 62 bonds and seals the barrier wall 61 to the bottom frame 10 and is arranged in the first mounting area 11. The second adhesive member 63 bonds and seals the barrier wall 61 to the bottom frame 10 and is arranged in the second mounting area 12.

In an embodiment, the first adhesive member 62 and the second adhesive member 63 are provided on opposite sides of the barrier wall 61 respectively. In this way, on one hand, the partition wall 61 is bonded and fixed to the bottom frame 10 by the first adhesive member 62 and the second adhesive member 63, so that the mounting strength and stability are high. On the other hand, the first adhesive member 62 and the second bonding member 63, which are bonded and fixed to the bottom frame 10, block an assembly gap between the barrier wall 61 and the bottom frame 10, thereby improving the sealing performance of the first barrier structure 60 and ensuring the blocking effect of the first barrier structure 60 on the leaked liquid.

In one embodiment, the barrier wall 61 is made of a rubber strip and constructed into a fence structure, so as to completely and effectively separate the first mounting area 11 from the second mounting area 12. The rubber strip has a simple structure, low cost and good water-blocking effect.

The first adhesive member 62 and the second adhesive member 63 can be any one of glue, tape, etc.

In one embodiment, the first function assembly 30 includes at least one mainboard. The liquid cooling assembly 50 includes at least one liquid cooling component, a liquid inlet pipe 51, and a liquid outlet pipe 52. The liquid cooling component is mounted on the mainboard to dissipate heat for the mainboard. The liquid inlet pipe 51 is in communication with a liquid inlet of the liquid cooling component, and the liquid outlet pipe 52 is in communication with a liquid outlet of the liquid cooling component.

During operation, the mainboard generates a huge amount of heat. The liquid inlet pipe 51 and the liquid outlet pipe 52 are respectively connected to an external coolant circulation device, so that the coolant flows into the liquid cooling component through the liquid inlet pipe 51, absorbs the heat from the mainboard through heat exchange, then carries the absorbed heat and flows out of the liquid cooling component from the liquid outlet pipe 52, and finally flows back to the coolant circulation device. The coolant continuously flows in a circulation flow path constructed by the coolant circulation device, the liquid inlet pipe 51, the liquid cooling assembly and the liquid outlet pipe 52, so as to ensure that the coolant flows into the liquid cooling component at all times to exchange heat with the mainboard, thereby continuously cooling the mainboard.

The liquid cooling component can adopt the liquid cooling structure in the prior art, such as a liquid cooling plate, a return pipe, etc., which can be flexibly selected according to actual needs.

Referring to FIG. 2 and FIG. 4, more specifically, in one embodiment, the at least one mainboard includes a first mainboard 31 and a second mainboard 32 that are arranged side by side. The at least one liquid cooling component includes a first liquid cooling component 53 and a second liquid cooling component 54. The first liquid cooling component 53 is mounted on the first mainboard 31, and the second liquid cooling component 54 is mounted on the second mainboard 32. The liquid cooling assembly 50 further includes a first liquid conveying pipe 57, a second liquid conveying pipe 57a, a first liquid return pipe 58, a second liquid return pipe 58a, a first liquid distributor 55, and a second liquid distributor 56.

The first liquid distributor 55 is connected to the liquid inlet pipe 51. One end of the first liquid conveying pipe 57 and one end of the second liquid conveying pipe 57a are both connected to the first liquid distributor 55, the other end of the first liquid conveying pipe 57 is connected to the first liquid cooling component 53, and the other end of the second liquid conveying pipe 57a is connected to the second liquid cooling component 54. One end of the first liquid return pipe 58 is connected to the first liquid cooling component 53, one end of the second liquid return pipe 58a is connected to the second liquid cooling component 54, and the other end of the first liquid return pipe 58 and the other end of the second liquid return pipe 58a are both connected to the second liquid distributor 56. The second liquid distributor 56 is connected to the liquid outlet pipe 52.

It should be understood that the first mainboard 31 and the second mainboard 32 can significantly enhance the computing capability of the server 100 and improve the data processing capability of the server 100. During operation, the first liquid cooling component 53 and the second liquid cooling component 54 respectively and independently dissipate heat for the first mainboard 31 and the second mainboard 32, so that the heat can be taken away by the coolant in time, and the working efficiency and the reliability of the server 100 are prevented from being affected duo to the abnormal temperature rise of the server 100.

The first liquid conveying pipe 57, the second liquid conveying pipe 57a, the first liquid return pipe 58, the second liquid return pipe 58a, the first liquid distributor 55 and the second liquid distributor 56 realize the parallel connection of the first liquid cooling component 53 and the second liquid cooling component 54, so that only one liquid inlet pipe 51 and one liquid outlet pipe 52 are configured to allow the coolant to flow into and out of the first liquid cooling component 53 and the second liquid cooling component 54 at the same time, thereby reducing the number of pipes used, reducing the difficulty of pipe layout and the occupied mounting space, reducing the manufacturing cost of the server 100 and helping to achieve a lightweight design.

The liquid inlet pipe 51 and the liquid outlet pipe 52 are both designed with a quick-disassembly structure. The liquid inlet pipe 51 and the liquid outlet pipe 52 with quick-disassembly structures can be quickly disassembled and replaced, and partial pipeline can be replaced, so that the production, processing and later maintenance are easier.

Optionally, the liquid inlet pipe 51 and the liquid outlet pipe 52 may be designed in any type of manual insertion quick connection, blind insertion quick connection, etc., so as to meet the diverse usage requirements of different users under different working conditions.

In order to improve the mounting reliability, both the liquid inlet pipe 51 and the liquid outlet pipe 52 are fixed to the bottom frame 10 through supporting members. The supporting members and the bottom frame 10 may be mounted in at least one of screw connection, snap connection, adhesive connection, magnetic connection, etc., which can be flexibly selected according to actual needs.

It should be noted that the above pipelines are all rubber pipes, which is convenient for being bent and laying pipes, reduces the difficulty of mounting, and avoids affecting the flow of coolant in the pipes.

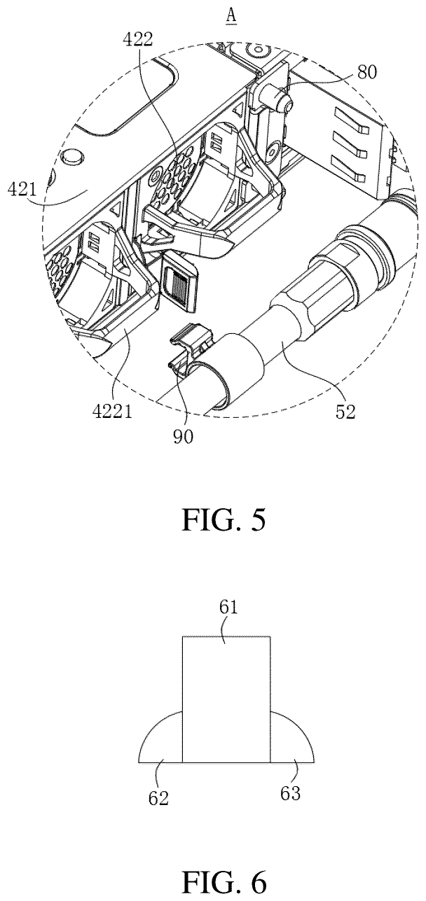

Referring to FIG. 4 and FIG. 5, in one embodiment, the second function assembly 40 includes a power supply 41 and a fan assembly 42. The power supply 41 is located closer to the first function assembly 30 than the fan assembly 42, and the fan assembly 42 is arranged at an edge of the bottom frame 10. The power supply 41 is located closer to the mainboard, which is more convenient for wiring to supply power to the mainboard. The fan assembly 42 is configured to blow air to heat-generating components such as the power supply 41 and the mainboard, so as to accelerate the air flow and take away the generated heat, thereby cooling the heat-generating components through air cooling.

That is, the fan assembly 42 cooperates with the liquid cooling assembly 50 to realize the composite cooling of air cooling and liquid cooling for the mainboard, thereby enhancing the heat dissipation efficiency.

In an embodiment, the fan assembly 42 includes a mounting box 421 and a plurality of fans 422. The mounting box 421 includes a plurality of mounting chambers arranged side by side on a side thereof away from the power supply 41. The plurality of fans 422 are mounted in the plurality of mounting chambers in a one-to-one correspondence. The plurality of fans 422 are integrally mounted in the mounting box 421, so as to realize the modular design of the fan assembly 42 and facilitate the mounting and dismounting of the fan assembly 42. Each fan 422 is independently mounted in corresponding mounting chamber, and is arranged in a regular manner without being affected by each other. In addition, since the plurality of fans 422 are provided, the air volume blowing toward the mainboard per unit time increases, thereby taking away more heat and enhancing the air cooling effect.

The mounting box 421 or the bottom frame 10 is provided with a positioning member 80. When in use, the server 100 is mounted into a cabinet body of a cabinet. A busbar protecting cover of the cabinet body is provided with a positioning bracket, and the positioning bracket is provided with a positioning hole. When the server 100 is pushed into the cabinet body, the positioning member 80 is engaged with the positioning hole, and meanwhile, a pin of the server 100 is butted with a busbar of the cabinet. By means of the positioning constraint provided by inserting the positioning member 80 into the positioning hole, the relative displacement between the pin and the busbar can be reduced or prevented, thereby effectively reducing the wear of the busbar and improving the voltage drop problem.

Referring to FIG. 5, in addition, in one embodiment, each fan 422 is provided with a handle 4221. The liquid inlet pipe 51 and the liquid outlet pipe 52 are both provided with a buckle 90. The buckle 90 is engaged with the handle 4221, such that the liquid inlet pipe 51 and the liquid outlet pipe 52 can be clamped tightly onto the handle 4221, that is, the liquid inlet pipe 51 and the liquid outlet pipe 52 can be positioned, and at the same time, the liquid inlet pipe 51 and the liquid outlet pipe 52 and their joints are prevented from being damaged due to collision with other structures.

Referring to FIG. 1 to FIG. 3, further, in one embodiment, the bottom frame 10 further includes a third mounting area 14 located on a side of the first mounting area 11 away from the second mounting area 12, and the server 100 further includes a third function assembly 90a provided in the third mounting area 14.

In addition, a second barrier structure 90b is provided on the bottom frame 10, and the second barrier structure 90b is arranged between the third mounting area 14 and the first mounting area 11.

When the liquid cooling assembly 50 leaks, the second barrier structure 90b is configured to prevent the leaked liquid from flowing into the third mounting area 14 and being in contact with the third function assembly 90a to damage the third function assembly 90a.

For example, the third function assembly 90a may include, but is not limited to, a hard disk module, a front IO module, etc.

In addition, according to an embodiment, a cabinet is provided, which includes a cabinet body and a plurality of servers 100 as described in any one of the above embodiments. The cabinet body is provided with a mounting cavity therein, and the plurality of servers 100 are stacked in the mounting cavity along a height direction of the cabinet body.

The cabinet body is provided with a liquid conveying pipeline and a liquid collecting tank that are connected to each other. One end of the liquid conveying pipeline away from the liquid collecting tank is connected to the liquid outlet 13, so that the leaked liquid discharged from the liquid outlet 13 in the server 100 can flow into the liquid collecting tank along the liquid conveying pipeline, thereby realizing the safe centralized recovery of the leaked liquid, so as to facilitate the subsequent centralized treatment of the leaked liquid, and at the same time prevent the leaked liquid from leaking into the cabinet body to cause damage to other functional components or electrical components.

In another embodiment, the liquid conveying pipeline can be omitted, and the leaked liquid discharged from the liquid outlet 13 is directly dripped into the liquid collecting tank.

The above-mentioned embodiments do not constitute a limitation on the protection scope of the technical solution. Any modifications, equivalent replacements and improvements made within the spirit and principles of the above-mentioned embodiments shall be included within the protection scope of this technical solution.

The foregoing descriptions are merely specific embodiments of the present disclosure, but are not intended to limit the protection scope of the present disclosure. Any variation or replacement readily figured out by a person skilled in the art within the technical scope disclosed in the present disclosure shall all fall within the protection scope of the present disclosure. Therefore, the protection scope of the present disclosure shall be subject to the protection scope of the appended claims.

What is claimed is:

1. A server, comprising:
a bottom frame comprising a first mounting area and a second mounting area, the bottom frame being provided with a liquid outlet in communication with the first mounting area;
a first function assembly provided in the first mounting area;
a second function assembly provided in the second mounting area;
a liquid cooling assembly cooperating with the first function assembly and configured to dissipate heat for the first function assembly;
a first barrier structure provided on the bottom frame and configured to separate the first mounting area from the second mounting area; and
a liquid guiding structure provided on the bottom frame and configured to guide a leaked liquid from the liquid cooling assembly to flow toward the liquid outlet.

2. The server according to claim 1, wherein the liquid guiding structure comprises a protrusion structure arranged in the first mounting area.

3. The server according to claim 1, wherein the liquid guiding structure comprises a protrusion structure and a sloping surface that are arranged in the first mounting area, the sloping surface has a first side and a second side that are opposite to each other, a height of the first side is greater than a height of the second side, the first side is connected to the protrusion structure, and the second side is connected to the liquid outlet.

4. The server according to claim 1, wherein the first barrier structure comprises a barrier wall and a first adhesive member, the barrier wall is provided on the bottom frame, the first adhesive member bonds and seals the barrier wall to the bottom frame, and the first adhesive member is arranged in the first mounting area or the second mounting area.

5. The server according to claim 1, wherein the first barrier structure comprises a barrier wall, a first adhesive member, and a second adhesive member; the barrier wall is provided on the bottom frame, the first adhesive member bonds and seals the barrier wall to the bottom frame and is arranged in the first mounting area, and the second adhesive member bonds and seals the barrier wall to the bottom frame and is arranged in the second mounting area.

6. The server according to claim 1, wherein the first function assembly comprises at least one mainboard, the liquid cooling assembly comprises at least one liquid cooling component, a liquid inlet pipe, and a liquid outlet pipe; the liquid cooling assembly is mounted on the mainboard to dissipate heat for the mainboard, the liquid inlet pipe is in communication with a liquid inlet of the liquid cooling component, and the liquid outlet pipe is in communication with a liquid outlet of the liquid cooling component.

7. The server according to claim 6, wherein the at least one mainboard comprise a first mainboard and a second mainboard that are arranged side by side, the at least one liquid cooling component comprises a first liquid cooling component and a second liquid cooling component, the first liquid cooling component is mounted on the first mainboard, the second liquid cooling component is mounted on the second mainboard.

8. The server according to claim 7, wherein the liquid cooling assembly further comprises a first liquid conveying pipe, a second liquid conveying pipe, a first liquid return pipe, a second liquid return pipe, a first liquid distributor, and a second liquid distributor;
wherein the first liquid distributor is connected to the liquid inlet pipe, one end of the first liquid conveying pipe and one end of the second liquid conveying pipe are both connected to the first liquid distributor, another end of the first liquid conveying pipe is connected to the first liquid cooling component, another end of the second liquid conveying pipe is connected to the second liquid cooling component, one end of the first liquid return pipe is connected to the first liquid cooling component, one end of the second liquid return pipe is connected to the second liquid cooling component, another end of the first liquid return pipe and another end of the second liquid return pipe are both connected to the second liquid distributor, and the second liquid distributor is connected to the liquid outlet pipe.

9. The server according to claim 6, wherein the liquid inlet pipe and the liquid outlet pipe are both designed with a quick-disassembly structure.

10. The server according to claim 1, wherein the second function assembly comprises a power supply and a fan assembly, and the power supply is located closer to the first function assembly than the fan assembly, and the fan assembly is arranged at an edge of the bottom frame.

11. The server according to claim 10, wherein the fan assembly comprises a mounting box and a plurality of fans, the mounting box comprises a plurality of mounting chambers arranged side by side on a side thereof away from the power supply, the plurality of fans are mounted in the plurality of mounting chambers in a one-to-one correspondence, and the mounting box or the bottom frame is provided with a positioning member configured to be engaged with a positioning hole of a cabinet body.

12. The server according to claim 11, wherein each fan is provided with a handle, the liquid inlet pipe and the liquid outlet pipe are both provided with a buckle, and the buckle is engaged with the handle.

13. The server according to claim 1, wherein the bottom frame comprises a third mounting area located on a side of the first mounting area away from the second mounting area, and the server further comprises a third function assembly provided in the third mounting area.

14. The server according to claim 13, further comprising a second barrier structure provided on the bottom frame, wherein the second barrier structure is arranged between the third mounting area and the first mounting area.

15. A cabinet, comprising:
a cabinet body provided with a mounting cavity therein; and
a plurality of servers according to claim 1, wherein the plurality of servers are stacked in the mounting cavity along a height direction of the cabinet body.
